(19) United States
(12) Patent Application Publication
(10) Pub. No.: US 2009/0230375 A1
(43) Pub. Date: Sep. 17, 2009

(54) Phase Change Memory Device

(75) Inventors: Chun-Sheng Liang, Puyan Township (TW); Tzyh-Cheang Lee, Hsinchu City (TW); Fu-Liang Yang, Hsinchu City (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/049,910

(22) Filed: Mar. 17, 2008

(51) Int. Cl. H01L 45/00; H01L 21/4763

(52) U.S. Cl. 257/2; 438/54; 257/E45.002; 257/E21.495

(57) ABSTRACT

A semiconductor device is provided which includes a substrate having a dielectric layer formed thereon, a heating element formed in the dielectric layer, a phase change element formed on the heating element, and a conductive element formed on the phase change element. The phase change element includes a substantially amorphous background and an active region, the active region capable of changing phase between amorphous and crystalline.

### BACKGROUND

The present disclosure relates generally to semiconductor devices and, more particularly, semiconductor device having a phase change memory portion.

An integrated circuit (IC) is formed by creating one or more devices (e.g., circuit components) on a semiconductor substrate using a fabrication process. As fabrication processes and materials improve, semiconductor device geometries have continued to decrease in size since such devices were first introduced several decades ago. However, the reduction in size of device geometries introduces new challenges that need to be overcome.

Phase change material used in some memory devices (“phase change memory devices”), generally exhibits two phases (or states), amorphous and crystalline. The amorphous state of the phase change material generally exhibits greater resistivity than the crystalline state. The state of the phase change material may be selectively changed by a stimulation, such as an electrical stimulation. Such electrical stimulation may be applied, for example, by supplying an amount of current through an electrode in contact with the phase change material. Phase change memory devices are a promising technology for next generation non-volatile memory because of good performance, endurance, and scalability. One of the major obstacles of phase change memory devices is the high reset current that is required to form the amorphous state in an active region of the phase change memory device. The reset current may depend on various factors such as contact area, structure, resistance, thickness, and thermal isolation. The reset current may be reduced by reducing the bottom electrode contact (“BEC”) area. However, reducing the contact area for consistent device performance is difficult due to variations in the critical dimension of the BEC during semiconductor processing.

Therefore, a need exists for a phase change memory device and method of making the same that has a reduced reset current.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a block diagram of an integrated circuit that embodies aspects of the present disclosure.

FIG. 2 is a circuit diagram of a memory cell that embodies aspects of the present disclosure.

FIG. 3 is a flowchart of a method for fabricating a memory device that may be utilized in the memory cell of FIG. 2.

FIGS. 4a-4i are sectional views of the memory device at various stages of fabrication in accordance with the method of FIG. 3.

FIG. 5 is a sectional view of an alternative embodiment of a memory device that may be utilized in the memory cell of FIG. 2.

FIGS. 6a & 6b are sectional views of a large active region in the memory devices of FIGS. 4 & 5.

FIGS. 7a & 7b are sectional views of a small active region in the memory devices of FIGS. 4 & 5.

### DETAILED DESCRIPTION

The present disclosure relates generally to semiconductor devices and more particularly, to a method of fabricating a memory device having features in an array and peripheral region. It is understood, however, that specific embodiments are provided as examples to teach the broader inventive concept, and one of ordinary skill in the art can easily apply the teaching of the present disclosure to other methods or devices. In addition, it is understood that the methods and apparatus discussed in the present disclosure include some conventional structures and/or processes. Since these structures and processes are well known in the art, they will only be discussed in a general level of detail.

Furthermore, reference numbers are repeated throughout the drawings for sake of convenience and example, and such repetition does not indicate any required combination of features or steps throughout the drawings. Moreover, the formation of a first feature over, on, adjacent, abutting, or coupled to a second feature in the description that follows may include embodiments in which the first and second features are formed in direct contact, and may also include embodiments in which additional features may be formed interposing the first and second features, such that the first and second features may not be in direct contact. Also, the formation of a feature on a substrate, including for example, etching a substrate, may include embodiments where features are formed above the surface of the substrate, directly on the surface of the substrate, and/or extending below the surface of the substrate (such as, trenches). A substrate may include a semiconductor wafer and one or more layers formed on the wafer.

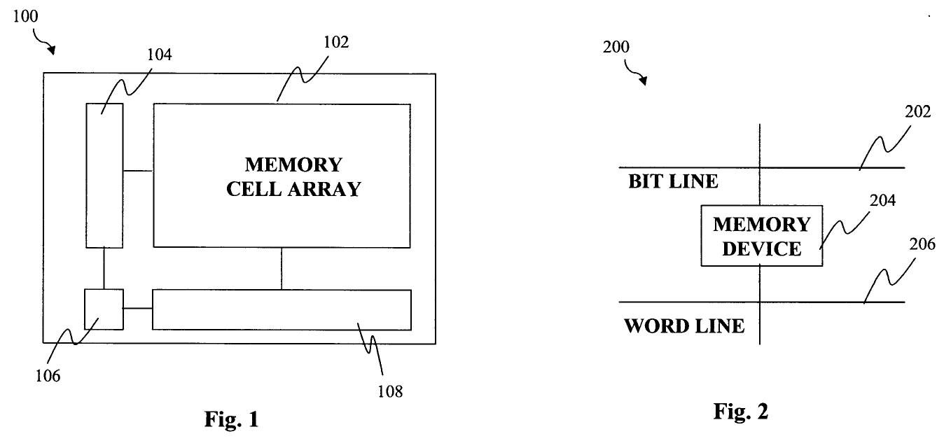

Referring to FIG. 1, illustrated is a block diagram of an integrated circuit (“IC”), indicated generally at 100, according to an illustrative embodiment. The IC 100 includes a memory cell array 102, and array logic/interface circuitries 104 and 106. The circuitry 104 includes various logic circuitries such as row/word latches, a decoder and/or a buffer. The circuitry 106 includes other logic circuitries such as column/bit/digit lines, a decoder, amplifiers, and/or a buffer. The IC 100 also includes a control circuitry 108. The circuitry 108 includes, for example, circuitries for input/output (“I/O”) timing and refresh control. Moreover, depending on the particular version of the illustrative embodiment, the geometric arrangement of the memory cell array 102 may vary. For example, in one version of the illustrative embodiment, the memory cell array 102 is located partially or substantially over the circuits 104, 106, and 108.

Referring to FIG. 2, illustrated is a circuit diagram of a memory cell, indicated generally at 200, according to the illustrative embodiment. The memory cell 200 includes a memory device 204, at least one word line 206, and at least one bit line 202. The memory cell 200 also includes semiconductor doped regions, conductive material, and/or electrical insulating material. The memory device 204 includes a plurality of semiconductor layers, each for storing at least one logical binary state. For example, in at least one version of the illustrative embodiment, the memory device 204 includes a layer for storing a logical binary state in response to thermal energy. In another version of the illustrative embodiment, the memory device 204 includes a layer for storing logical binary state in response to a magnetic field. In both versions, the response is associated with a detectable change in the electrical and/or crystalline properties of the layer's material, to provide one or more memory functions. For example, the word line 206 includes at least one conductive interconnect proximate the memory device 204 such that the word line 206 provides a current to induce heating in the memory device 204. Similarly, the bit line 202 includes at least one conductive interconnect proximate the memory device 204 for reading information from and/or writing information to the memory device 204.

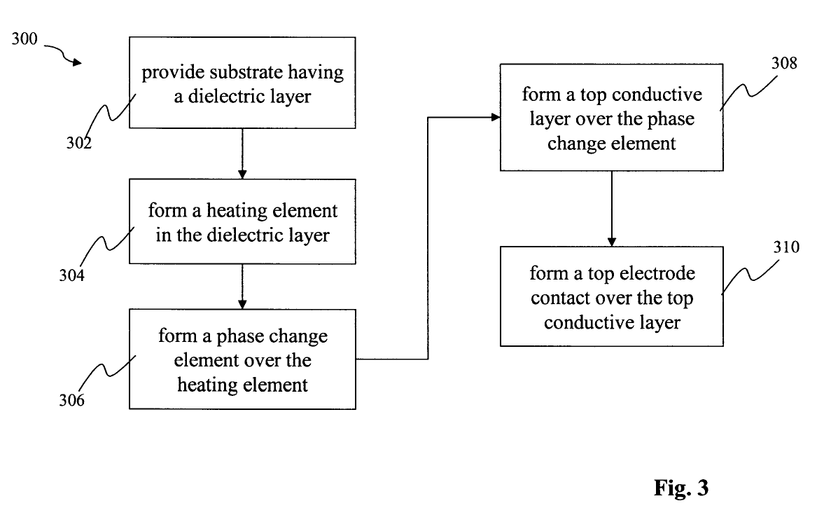

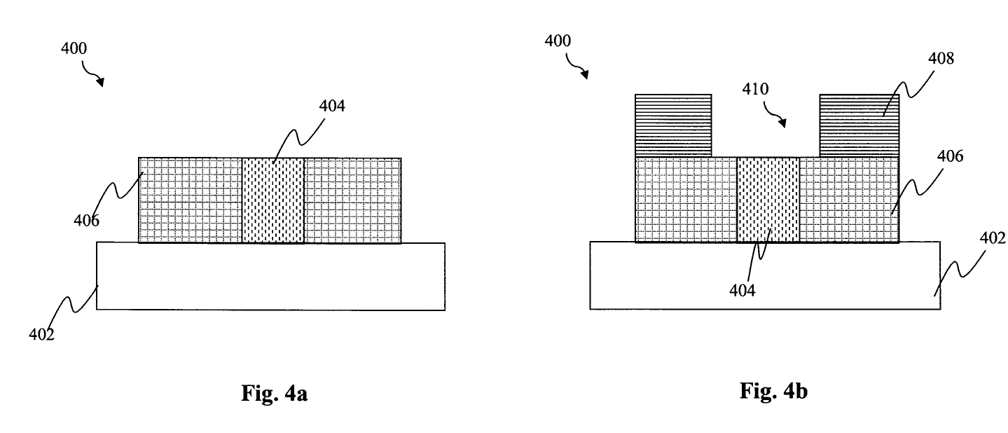

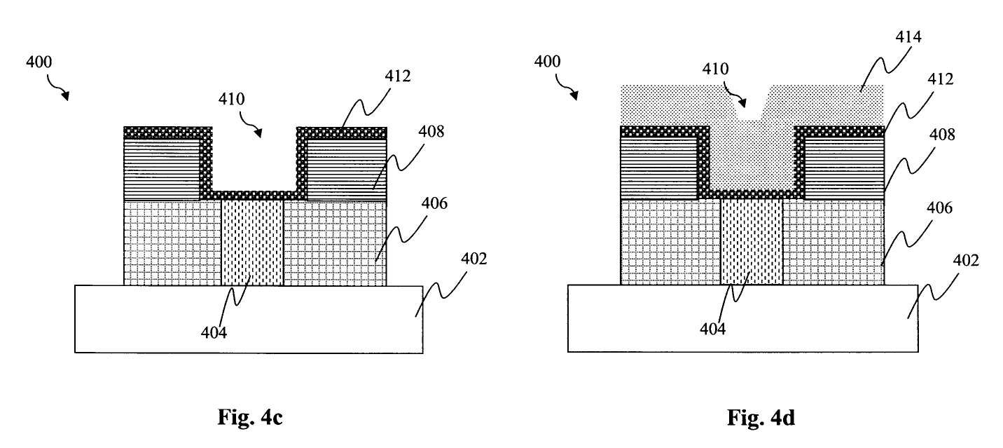

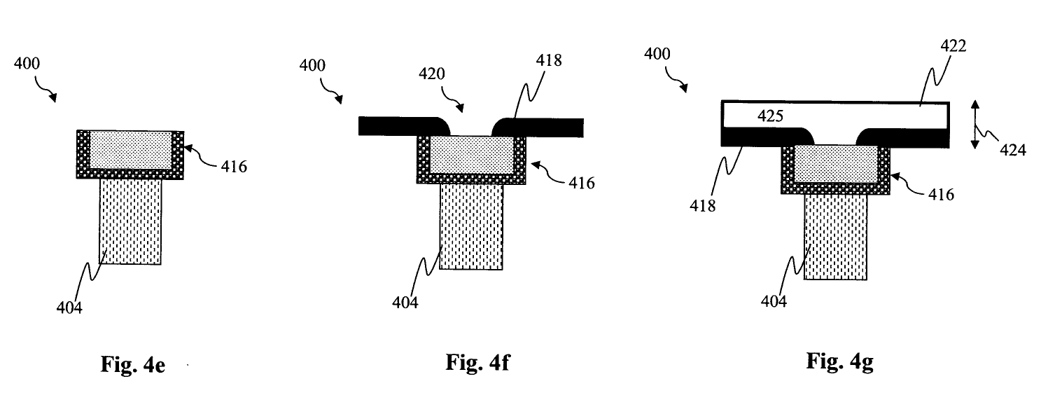

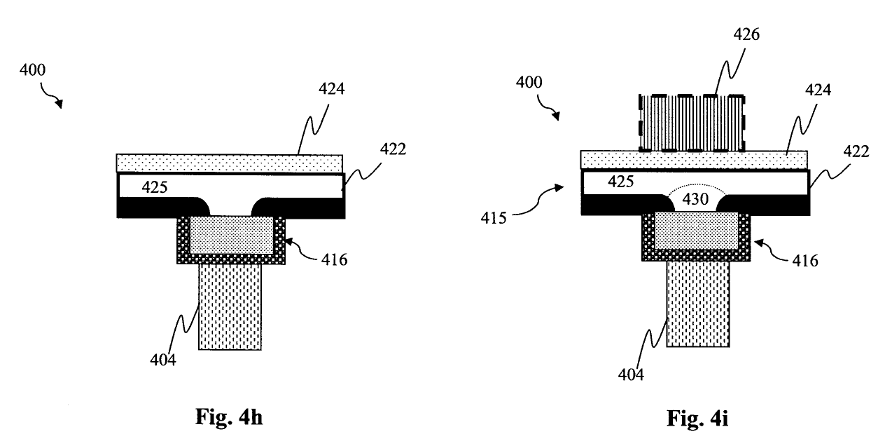

Referring to FIG. 3, illustrated is a flowchart of a method 300 for fabricating a memory device 400 according to an illustrative embodiment. Referring also to FIGS. 4a-4i, illustrated are cross-sectional views of the memory device 400 at various stages of fabrication in accordance with the method 300 of FIG. 3. The memory device 400 is representative of the memory device 204 of FIG. 2. It is understood that the memory device 400 illustrated in FIGS. 4a-4i may include various semiconductor layers, such as doped layers, insulative layers, epitaxial layers, conductive layers including polysilicon layers, and dielectric layers, but is simplified to illustrate a phase change portion of the memory device for a better understanding of the disclosed embodiments herein.

In FIG. 4a, the method 300 begins with block 302 in which a substrate 402, such as a semiconductor wafer, is provided. The substrate 402 includes one or more active devices such as transistors formed therein. The substrate 402 may include silicon in a crystalline structure. In alternative embodiments, the substrate 402 may optionally include other elementary semiconductors such as germanium, or may include a compound semiconductor such as, silicon carbide, gallium arsenide, indium arsenide, or indium phosphide. Additionally, the substrate 402 may include a silicon on insulator (SOI) substrate, polymer-on-silicon substrate. In another embodiment, the substrate 402 also includes an air gap for providing insulation for the memory device 400. For example, the substrate 402 includes a “silicon-on-nothing” (“SON”) substrate including a thin insulation layer. The thin insulation layer includes air and/or other gaseous composition. The substrate 402 may further comprise one or more layers formed on the substrate. Examples of layers that may be formed include doped layers, insulative layers, epitaxial layers, conductive layers including polysilicon layers, dielectric layers, and/or other suitable semiconductor layers.

The memory device 400 includes a bottom electrode contact 404 formed in a dielectric layer such as a silicon oxide layer 406. The bottom electrode contact (“BEC”) 404 may include a plug formed by patterning and etching a trench in the silicon oxide layer 406 and filling the trench with a conducting material such as tungsten, and then etched back. The plug may include other conducting materials such as copper, aluminum, tantalum, titanium, nickel, cobalt, metal silicide, metal nitride, and polysilicon.

The method 300 continues with block 304 in which a heating element 416 (in FIG. 4e) is formed on the BEC 404. In FIG. 4b, a dielectric layer such as a silicon oxide layer 408 may be deposited over the BEC 404 and the silicon oxide layer 406. The silicon oxide layer 408 may then be patterned and etched to form a crown feature 410 directly over the BEC 404. Such patterning process includes wet and/or dry etching employing a mask, masking process, and/or photolithographic process.

In FIG. 4c, a heating layer 412 such as a layer of TiN may be deposited over the crown feature 410 and silicon oxide layer 408. The heating layer 412 partially fills the crown feature and has a thickness of about 5 nm to about 25 nm. The heating layer 412 may be formed by atomic layer deposition (“ALD”), chemical vapor deposition (“CVD”), metal-organic CVD (“MOCVD”), plasma-enhanced CVD (“PECVD ”), and/or other suitable techniques.

In FIG. 4d, a silicon oxide layer 414 may be deposited over the heating layer 412 to substantially fill in the crown feature 410. In FIG. 4e, a planarization process such as a chemical mechanical planarization (chemical mechanical polishing or “CMP”) process may be performed on the silicon oxide layer 414 and a portion of the heating layer 412 to form the planarized heating element 416. The planarizing process may alternatively or collectively include an etch back or other suitable process. It is understood that the memory device 400 illustrated in FIGS. 4e-4i includes the various features described in FIGS. 4a-4d but is further simplified for a better understanding of the disclosed embodiments.

The method 300 continues with block 306 in which a phase change element 415 (in FIG. 4i) is formed over the heating element 416. In FIG. 4f, a dielectric layer 418 may be formed over the heating element 416 by a suitable deposition technique. The dielectric layer 418 may include silicon-rich nitride, silicon oxy-nitride, and other suitable material. The dielectric layer 418 may then be patterned and etched to form a trench 420. The trench 420 may have a width that is less than about 25 nm and may be centrally positioned over the heating element 416. In FIG. 4g, a phase change material layer 422 may be deposited over the dielectric layer 418 filling the trench 420.

The phase change material layer 422 includes a chalcogenide material or one or more other suitable materials, which exhibit a change in their electrical characteristics (e.g., resistivity) in response to an induced stimulus (e.g., electrical current). In a chalcogenide material, such an exhibition of a change in its electrical characteristics is caused by an associated change in its phase (e.g., from an amorphous phase to a crystalline phase, and vice versa) in response to the induced stimuli. Accordingly, in response to an induced stimulus, the phase change element 415 is capable of performing a conventional memory function (e.g., store a binary state) of the memory device 400 as will discussed in later.

In the present example, the phase change material layer 422 preferably includes a Ge—Sb—Te (“GST”) alloy. Alternatively, other suitable materials for the phase change material layer 422 optionally include Si—Sb—Te alloys, Ga—Sb—Te alloys, As—Sb—Te alloys, Ag—In—Sb—Te alloys, Ge—In—Sb—Te alloys, Ge—Sb alloys, Sb—Te alloys, Si—Sb alloys, and combinations thereof.

The phase change material layer 422 is configured to be substantially amorphous 425 following back-end-of-line (“BEOL”) semiconductor processing. In the present example, the phase change material layer 422 may be deposited with a thickness 424 that is less than about 20 nm and a deposition temperature that is less than about 200° C. The phase change material layer 422 may be deposited by a physical vapor deposition (“PVD”) (also referred to as “sputtering”) process. The specified thickness (e.g., less than about 20 nm) and deposition temperature (e.g., less than about 200° C.) will aid in preventing crystallization and nuclei formation during the deposition process, and thus promote formation of an amorphous background 425. However, some nuclei formation may exist in the amorphous background 425 but the size of the nuclei may be less than about 3 nm. Further, the interfacial energy dominates as the thickness 424 of the phase change material layer 422 decreases, which results in the amorphous background 425 even with experiencing BEOL processing.

Alternatively, the phase change material layer 422 may optionally be formed by sputtering (of GST) and the layer may be doped with silicon (Si) or nitrogen (N) by an ion implantation process. The concentration of Si or N in the resultant layer is about 2% to about 25%. The doping of Si or N may increase the crystallization temperature of the phase change material layer 422, and thus may aid in preventing crystallization of the phase change material. Additionally, the Si or N may optionally be added to the phase change material layer 422 (such as GST) by a co-sputtering process or reactive sputtering process using nitrogen as the reactive gas and argon as the inert gas. In another embodiment, the amorphous background may be formed by a pre-amorphization implantation (“PAI”) process. PAI involves implanting a species such as silicon (Si) or germanium (Ge) to amorphize the material layer.

In FIG. 4h, the method 300 continues with block 308 in which a top conductive layer 424 is formed over the phase change material layer 422. The top conductive layer 424 may be amorphous and may include a metal nitride (e.g., TiN or TaN), metal silicon nitride, or carbon. The top conductive layer 424 may be formed by atomic layer deposition (“ALD”), chemical vapor deposition (“CVD”), metal-organic CVD (“MOCVD”), plasma-enhanced CVD (“PECVD”), evaporation, and/or other suitable techniques. The top conductive layer 424 may serve as an amorphous capping layer to reduce a seeding effect and prevent nucleating of the phase change material layer 422 from the capping layer. Accordingly, the amorphous top conductive layer 424 may aid in preventing crystallization of the phase change material 422. The phase change material layer 422 and top conductive layer 424 may be patterned to form a phase change memory cell of the memory device 400. Such patterning process includes wet and/or dry etching employing a mask, masking process, and/or photolithographic process.

In FIG. 4i, the method 300 continues with block 310 in which a top electrode contact (“TEC”) 426 may be formed on the top conductive layer 424. The TEC 426 may include copper tungsten, gold, aluminum, carbon nano-tubes, carbon fullernes, refractory metals, and/or other materials, and may be formed by CVD, ALD, PVD, damascene, dual-damascene, and/or other suitable processes. It is understood that further processing may be performed on the memory device 400 such as formation of interconnect metal layers and inter-metal dielectric.

As previously noted, the phase change element 415 of the memory device 400 has an amorphous background 425. The phase change element 415 further includes an active region 430 (within the amorphous background 425) that is capable of changing phase between amorphous and crystalline in response to an induced stimulus (such as an electrical current). When the active region 430 is in the amorphous state, the resistivity of the phase change element 415 is relatively high. When the active region 430 is in the crystalline state, the resistivity of the phase change element 415 is relatively low.

Thus, in response to the induced stimulus, the phase change element 415 is capable of performing a conventional memory function (e.g., store a binary state) of the memory device 400. The amorphous background 425 of the phase change element 415 has a lower thermal conductivity than that of a silicon oxide and crystalline background. Accordingly, the amorphous background 425 provides for better thermal isolation of the phase change element 415 thereby reducing a reset current that is required to form the phase of the active region 430 to the amorphous state. It has been observed that the reset current may be reduced by a factor of about 3 when using an amorphous background instead of a crystalline background. It should be noted that the set current (e.g., current required to form the phase of the active region 430 to the crystalline state) is typically lower than the reset current.

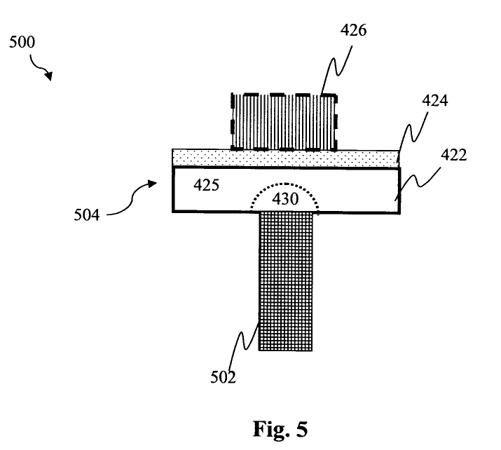

Referring to FIG. 5, illustrated is an alternative embodiment of a memory device 500 that is representative of the memory device 204 of FIG. 2. It is understood that the memory device 500 may include various semiconductor layers, such as doped layers, insulative layers, epitaxial layers, conductive layers including polysilicon layers, and dielectric layers, but is simplified to illustrate a phase change portion of the memory device for a better understanding of the disclosed embodiments herein. The memory device 500 of FIG. 5 is similar to the memory device 400 of FIG. 4i except for the differences noted below. Similar features in FIGS. 4i and 5 are numbered the same for clarity. The memory device 500 includes a BEC 502 that is direct contact with a phase change element 504. The BEC 502 may be formed by a similar process that was used to form the BEC 404 in FIG. 4a. The phase change element 504 is similar to the phase change element 415 of FIG. 4i except that the insulating portion 418 with the trench 420 may be omitted. The phase change element 504 may be centrally positioned on the BEC 502. The phase change element 504 has an amorphous background 425 and an active region 430 (within the amorphous background) that is that is capable of changing phase between amorphous and crystalline in response to an induced stimulus (such as an electrical current). The memory device 500 further includes a top conductive layer 424 formed on the phase change element and a TEC 426 formed on the top conductive layer as discussed in FIGS. 4h and 4i. As previously noted, the amorphous background 425 provides for better thermal isolation of the phase change element 415 thereby reducing a reset current that is required to reset the phase of the active region 430 to the amorphous state.

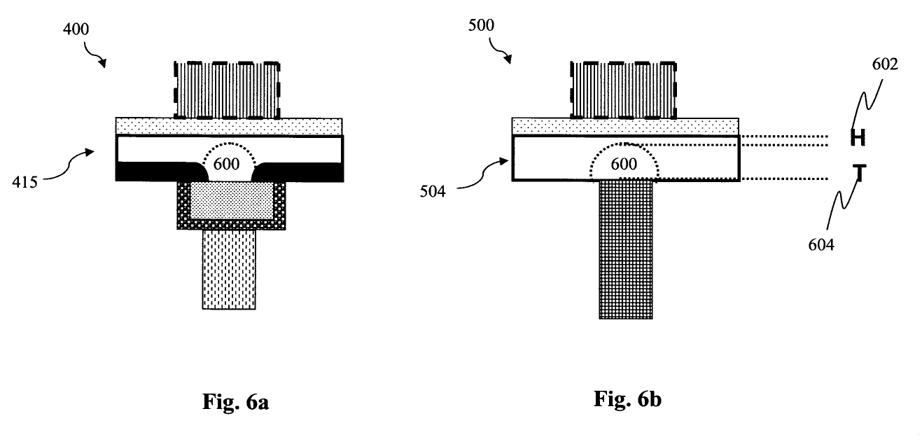

Referring to FIGS. 6a and 6b, illustrated are the memory device 400 of FIG. 4i and the memory device 500 of FIG. 5, respectively, each with a large active region 600. The phase change element 415, 504 has a thickness (H) 602 and the active region 600 has a thickness (T) 604. The thickness (H) 602 of the phase change element 415, 504 is greater than the thickness (T) 604 of the active region 600. In this configuration (where H>T), the memory devices 400, 500 provide for a higher on/off ratio associated with a difference in resistivity of the amorphous state and the crystalline state of the phase change element 415, 504. Accordingly, the state of the phase change element can be easily detected thereby improving the performance of the memory devices 400, 500.

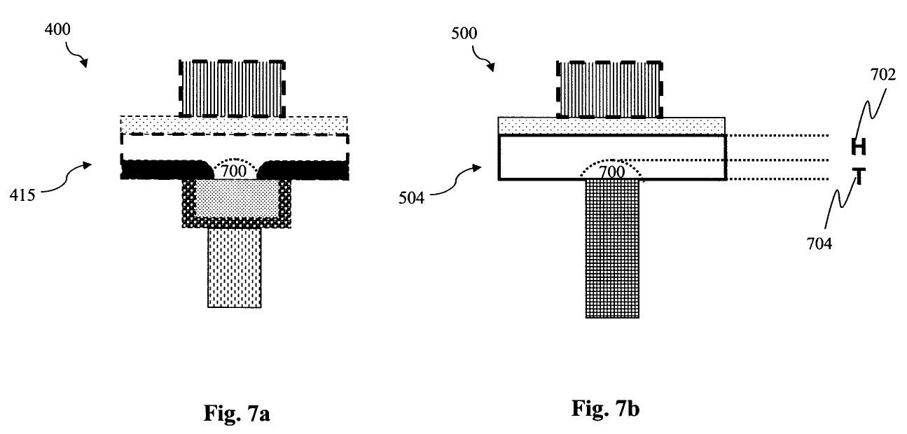

Referring to FIGS. 7a and 7b, illustrated are the memory device 400 of FIG. 4i and the memory device of 500 of FIG. 5, respectively, each with a small active region 700. The phase change element 415, 504 has a thickness (H) 702 and the active region 700 has a thickness (T) 704. The thickness (H) 702 of the phase change element 415, 504 is less than the thickness (T) 704 of the active region 700. In this configuration (where H<T), the memory devices 400, 500 provide for a lower programming current (e.g., set and reset current), and thus less power is required to operate the memory devices.

Thus provided is a semiconductor device which includes a substrate having a dielectric layer, a heating element formed in the dielectric layer, a phase change element formed on the heating element, and a conductive element formed on the phase change element. The phase change element includes a substantially amorphous background and an active region, the active region capable of changing phase between amorphous and crystalline. In some embodiments, the phase change element is of one of a Ge—Sb—Te alloy, Si—Sb—Te alloy, Ga—Sb—Te alloy, As—Sb—Te alloy, Ag—In—Sb—Te alloy, Ge—In—Sb—Te alloy, Ge—Sb alloy, Sb—Te alloy, Si—Sb alloy, and combinations thereof. In other embodiments, the phase change element includes dopants of the type selected from the group consisting of: silicon, nitrogen, and combinations thereof. In some other embodiments, the dopant concentration is about 2% to about 25%.

In still other embodiments, the phase change element has a thickness that is less than 20 nm. In some other embodiments, the amorphous background includes nuclei that are less than 3 nm. In other embodiments, the conductive element is amorphous. In some other embodiments, the conductive element is of a type selected from the group consisting of: a metal nitride, a metal silicon nitride, and a carbon. In other embodiments, the semiconductor device further includes an insulating portion having a trench that is located on the heating element. In other embodiments, the trench has a width that is less than about 25 nm. In still other embodiments, the insulating portion includes a silicon-rich nitride.

Also, a method of fabricating a semiconductor device is provided which includes the steps of: providing a substrate having a dielectric layer formed thereon, forming a heating element in the dielectric layer, forming a phase change element on the heating element, and forming a conductive element on the phase change element. The phase change element includes a substantially amorphous background and an active region, the active region capable of changing phase between amorphous and crystalline. In some embodiments, the step of forming the phase change element having the substantially amorphous background is by a sputtering process. In some other embodiments, the sputtering process is one of a reactive sputtering process and a co-sputtering process. In other embodiments, the sputtering process utilizes nitrogen as a reactive gas.

In still other embodiments, the step of forming the phase change element having the substantially amorphous background is by an ion implantation process. In some embodiments, the ion implantation process utilizes dopants of a type selected from the group consisting of: a silicon, a germanium, and a nitrogen. In some other embodiments, the step of forming the phase change element includes depositing a phase change material layer at a temperature less than about 200° C. In other embodiments, the step of forming the phase change element includes: depositing an insulating layer over the heating element, forming a trench in the insulating layer, the trench being located directly over the heating element, and depositing a phase change material layer over the insulating layer and filling in the trench.

Further, a semiconductor device is provided which includes a substrate having at least one active device formed therein, a dielectric layer formed over the substrate, a bottom conductive element formed in the dielectric layer, a phase change element formed over the bottom conductive element, and a top conductive element formed over the phase change element. The phase change element includes a substantially amorphous background and an active region within the amorphous background, the active region capable of changing phase between amorphous and crystalline.

Although only a few exemplary embodiments of this invention have been described in detail above, those skilled in the art will readily appreciate that many modifications are possible in the exemplary embodiments without materially departing from the novel teachings and advantages of this invention. It is understood that various different combinations of the above-listed steps can be used in various sequences or in parallel, and there is no particular step that is critical or required. Also, features illustrated and discussed above with respect to some embodiments can be combined with features illustrated and discussed above with respect to other embodiments. Accordingly, all such modifications are intended to be included within the scope of this invention.

Several different advantages exist from these and other embodiments. The phase change memory device and method of the same disclosed herein provide for a phase change element that has an amorphous background for improved thermal isolation of the phase change element. Accordingly, the reset current required to form the amorphous state in the active region of the phase change memory device is reduced. Since the phase change memory cell size is limited by the reset current, the phase change memory device disclosed herein may be used for next generation non-volatile memory devices.

What is claimed is:

1. A semiconductor device, comprising:
a substrate having a dielectric layer formed thereon;
a heating element formed in the dielectric layer;
a phase change element formed on the heating element; and
a conductive element formed on the phase change element;
wherein the phase change element includes a substantially amorphous background and an active region, the active region capable of changing phase between amorphous and crystalline.

2. The semiconductor device of claim 1, wherein the phase change element is of a type selected from the group consisting of: Ge—Sb—Te alloy, Si—Sb—Te alloy, Ga—Sb—Te alloy, As—Sb—Te alloy, Ag—In—Sb—Te alloy, Ge—In—Sb—Te alloy, Ge—Sb alloy, Sb—Te alloy, Si—Sb alloy, and combinations thereof.

3. The semiconductor device of claim 1, wherein the phase change element includes dopants of the type selected from the group consisting of: silicon, nitrogen, and combinations thereof.

4. The semiconductor device of claim 3, wherein the dopant concentration is about 2% to about 25%.

5. The semiconductor device of claim 1, wherein the phase change element has a thickness that is less than 20 nm.

6. The semiconductor device of claim 1, wherein the amorphous background includes nuclei that are less than 3 nm.

7. The semiconductor device of claim 1, wherein the conductive element is amorphous.

8. The semiconductor device of claim 1, wherein the conductive element is of a type selected from the group consisting of: a metal nitride, a metal silicon nitride, and a carbon.

9. The semiconductor device of claim 1, further comprising an insulating portion having a trench that is located on the heating element.

10. The semiconductor device of claim 9, wherein the trench has a width that is less than about 25 nm.

11. The semiconductor device of claim 9, wherein the insulating portion includes a silicon-rich nitride.

12. A method of fabricating a semiconductor device, comprising:
providing a substrate having a dielectric layer formed thereon;
forming a heating element in the dielectric layer;
forming a phase change element on the heating element; and
forming a conductive element on the phase change element;
wherein the phase change element includes a substantially amorphous background and an active region, the active region capable of changing phase between amorphous and crystalline.

13. The method of claim 12, wherein the forming the phase change element having the substantially amorphous background is by a sputtering process.

14. The method of claim 13, wherein the sputtering process is one of a reactive sputtering process and a co-sputtering process.

15. The method of claim 14, wherein the sputtering process utilizes nitrogen as a reactive gas.

16. The method of claim 12, wherein the forming the phase change element having the substantially amorphous background is by an ion implantation process.

17. The method of claim 16, wherein the ion implantation process utilizes dopants of a type selected from the group consisting of: a silicon, a germanium, and a nitrogen.

18. The method of claim 12, wherein the forming the phase change element includes depositing a phase change material layer at a temperature less than about 200° C.

19. The method of claim 12, wherein the forming the phase change element includes:
depositing an insulating layer over the heating element;
forming a trench in the insulating layer, the trench being located directly over the heating element; and
depositing a phase change material layer over the insulating layer and filling in the trench.

20. A semiconductor device, comprising:
a substrate having at least one active device formed therein;
a dielectric layer formed over the substrate;
a bottom conductive element formed in the dielectric layer;
a phase change element formed over the bottom conductive element; and
a top conductive element formed over the phase change element;
wherein the phase change element includes a substantially amorphous background and an active region within the amorphous background, the active region capable of changing phase between amorphous and crystalline.
